(19) United States
(12) Patent Application Publication
(10) Pub. No.: US 2005/0030118 A1
(43) Pub. Date: Feb. 10, 2005

(54) Broadband access transmission network integrating the functions of electric power network, telecommunication network, tv network and internet

(76) Inventor: Deging Wang, Hubei (CN)

Correspondence Address: BIRCH STEWART KOLASCH & BIRCH, PO BOX 747, FALLS CHURCH, VA, 22040-0747, US

(21) Appl. No.: 10/496,661

(22) PCT Filed: Oct. 30, 2002
(86) PCT No.: PCT/CN02/00767

(30) Foreign Application Priority Data
May 25, 2004 (CN) 01138240.6

(51) Int. Cl. H03H 5/00

(52) U.S. Cl. 333/24 R

(57) ABSTRACT

A broadband access transmission network integrating the functions of electric power network, communication network, TV network and Internet relates to network transmission. It includes a broadband transmission network of 10 KV power distribution network and a broadband transmission network of low-voltage power distribution network. These two transmission networks are connected via distribution transformers and optical fiber connectors. The broadband transmission network of 10 KV power distribution network is composed of optical compound power lines, wires, transformer substations, machine rooms, taps, insulating jackets, insulating waterproofing outer jackets and optical fiber connectors. The broadband transmission network of low-voltage power distribution network is composed of optical compound power lines, coaxial cable compound power lines, taps, insulating jackets, optical access points, distributors, modems and two-way amplifiers. The invention can perform high-speed broadband communication and power transmission on the same compound wires. It utilizes the existing power network sufficiently and prevents the cost of rebuilding the communication network, cable TV network and Internet, and can simultaneously perform building, operating, maintaining and managing of these networks.

### FIELD OF THE INVENTION

This invention relates to a broadband access transmission network, especially to a “4-in-1” broadband transmission network integrating the functions of electric power network, telecommunication network, TV network and Internet, which belongs to the field of network transmission.

### DESCRIPTION OF THE PRIOR ART

To realize high-speed broadband communication over electric power transmission network is to construct the high-speed broadband communication network and the electric power transmission network one-and-for-all by taking advantage of new compound electric power technology during the construction of electric power transmission networks. And this can maintain or administrate the high-speed broadband communication transmission network while running, maintaining or administrating the electric power network as well. This can make full use of the resources of electric power transmission network, such as towers, channels, wire stocks, galleries and path-right routings, etc. That is, while providing reliable electric power to customers, it provides real broadband transmission network access services to customers required. It is reported that over 60 companies in advanced countries, such as America, Germany, Israel, Japan, Korea, Swiss, etc., as well as China are trying to research on electric power line networking to realize pure electric power line broadband communication technique. But, it is still immature for the moment and the future is distant. The reason lies in that they are only trying to manufacture a kind of “car” that runs as fast as possible, but whether the “road” can make it fast is out of their control. In addition, some problems such as variable load, interference, bandwidth, noise, security and the like of electric power network are hard to solve. How to construct a network of information highways to make any “information car” go fast, is an important task at present and for the future, and it is also the key for the development of information industry modernization. It will bring not only large benefits to the country, society and consumers, but also a great potential to the development of information industry of our country.

After our telecommunication market is open, how to promote the high-speed development of our information industry to compete fairly with foreign telecommunications when they enter our telecommunication market is a problem. Making use of electrical power network is the biggest advantage as it can reach and exist everywhere and no other network is compatible with it. As long as the resources are developed, it can be used for multiple purposes with one network.

In the aspect of backbone network implementation, nation-wide broadband network interconnection will be realized with the interconnection of national electric power networks. For example, Sending West Power to the East is one of them. National backbone network is mainly formed by interconnecting electric power networks between factories and stations such as large electricity factory, electricity transmission/transformation station, electric current exchange station, etc. to realize network interconnection. That is, to modify the overhead ground lines of high-voltage power transmission lines with the voltage range from 110 KV to 500 KV as well as above by replacing them (required by the route) with optical compound overhead ground fiber. Thus all counties (cities) of the country are connected, and then all towns (including small village and streets) are connected together by fibers of the county (city) compound network of power supply and broadband, which realizes all optical networks of the whole country. At present, each county (city) in our country has one or more 110 KV transformer substation in average. It is very easy to realize national all optical network by making use of the resources of electric power transmission networks and the investment reduction is all very surprising. It doesn't need large amount of people to dig ditches and bury cables “from south to north and tramping over hill and dale” any more.

In the aspect of access network, high-speed broadband communication can be realized by making use of huge electric power access network and large amount of access users of electric power system. As long as electricity is used, the electric power line must reach the house, i.e. extending the information highway to the gate of each customer even each room and really realizing broadband communication and “4-in-1 network” (means the transmission network integrating the functions of electric power network, TV network, telecommunication network and Internet), that is, four purposes via one network. It will provide a real broadband physical network platform that can be shared by all people for all telecommunication operators as well as the approaching of broadband “stream media” technology. It will not only solve the last one mile problem of broadband communication network but also the problem of within 10 meters. At the same time, it can work together and complement with wireless access to realize wireless broadband access network.

And at present, the electric power network of our country only works for transferring electric power. Although a fiber has been added onto the high-voltage backbone electric power network it only works for the communication within backbone network and the resources haven't been made best use of. The key to realize the effects and values of the network is to access customers, otherwise, all efforts will be unnecessary, and the key to access customer is the broadband access transmission network.

### SUMMARY OF THE INVENTION

The object of this invention is to provide a method to realize the transmission of high-speed broadband communication, cable TV and electric power via one compound wire by making full use of resources such as towers, channels, wire stocks, galleries and path-right routings and the like so as to realize a “4-in-1 network” without duplicate construction, and then completely solve the difficulty of broadband network access, the problem of electric power lines, TV coaxial cables, TV fibers, telecommunication fibers on the same wire pole as well as current status of cobweb-like networks over the city and street. And this can realize the broadband access transmission network with easy implementation and convenient maintain/administration by integrating the functions of electric power network, telecommunication network, TV network and Internet.

This invention realizes the object described above by following technical solutions.

The broadband access transmission network integrating the functions of electric power network, telecommunication network, TV network and Internet includes the broadband transmission network of 10 KV power distribution network and the broadband access transmission network of low-voltage power distribution network. These two transmission networks are connected via the distribution transformer 8 and the optical fiber connector 13; the broadband transmission network of 10 KV power distribution network comprises the optical compound power lines 1, power wires L1 and L3, transformer substation 3, machine room 4, taps 5, insulating waterproofing outer jacket 6, insulating jacket 7, and optical fiber connector 13; The broadband access transmission network of low-voltage power distribution network comprises the optical compound power lines 1, coaxial cable compound power lines 2, power wires L1 and L3, taps 5, insulting jacket 7, optical node 9, distributor 10, modems 11 and two-way amplifiers 12. It is characterized in that: The optical compound power lines 1 and power wires (L1, L3) of the broadband transmission network of 10 KV power distribution network connect with the transformer substation 3; One end of the fiber compound power line 1 is connected with machine room 4 via taps 5, insulating waterproofing outer jacket 6 and insulating jacket 7; machine room 4 is connected with the fiber compound lines of backbone network G via taps 5; the other end of the fiber compound power line 1 is connected with fiber connector 13 via taps 5, insulating waterproof outer jacket 6 and insulating jacket 7; one end of the fiber compound power line of broadband access transmission network of low-voltage power distribution network is connected with fiber connector 13 via taps 5 and insulating jackets 7, and the other end is connected with coaxial cable compound lines 2 via taps 5 and fiber node 9; coaxial cable compound line 2 is equipped with two-way amplifier 12, which is connected with client modem 11 via coaxial cable compound lines 2 and distributor 10; the fiber compound power lines 1 of all optical broadband access transmission network of low-voltage power distribution network is connected with client terminal 19 via optical splitter 18; the fiber compound power lines 1 of wireless broadband access transmission network of low-voltage power distribution network are equipped with radio transceiver 20 that matches with the fixed terminal 21 and mobile terminal 22 of customer. The optical compound power line 1 is the compound power line composed by fiber, insulating socket and power transmission conductor. The coaxial compound line 2 is the compound power line composed by inner conductor, insulation protection layer, load-carrying layer and electric power transmission layer. The function of tap 5 is to shunt the optical fibers in fiber compound electric power line 1. The shunting deploys twice-reinforcement. For the first time, aging-resistant compound insulating soft-ring 28 is used to trap the whole wire and fiber element 26 as well as insulating jacket 7, and then the fastening element 27 is used to bind. For the second time, aging-resistant compound insulating soft-ring 28 is used to trap the whole wire and fiber element 26 as well as insulating jacket 7 and insulating waterproof outer jacket 6, and then the fastening element 27 is used to bind. Reference numeral 32 is the standby stuffing conductor band, whose function is to fill the empty position of fiber element 26 when the fiber element 26 is detached from the wire to keep the wholly uniform force adding when the wire is clasped. Insulating waterproof outer jacket 6 and insulating jacket 7 have the protection function for fiber element 26. The surface of insulating waterproof outer jacket 6 is equipped with waterproof apron 29 and both ends are equipped with female buckle 30 and male buckle 31. Insulating waterproof outer jacket 6 is a kind of plastic compound soft insulating material. Female buckle 30 can tightly trap male buckle 31 by thermoplastic to realize extended connection. Insulating waterproof outer jacket 6 traps on the insulating jacket 7, and the insulating jacket 7 traps on the fiber element 26. They are both fixed with the wire via taps 5. It is also possible for Taps 5 in 220/380V low-voltage power distribution network not to use insulating waterproof outer jacket 6.

The advantages of this invention are:
1. Electric power transmission for high-speed broadband communication can be realized by a single compound wire. Where there is electricity, there is information highway. This can make full use of the resources of electric power transmission network, such as towers, channels, wire stocks, galleries and path-right routings, etc. to invest in the construction of “4 networks” at one time and perform running, maintenance and administration of “4 networks” simultaneously without additional wiring investment, and then completely solve the problem of the wire pole with electric power lines, TV coaxial cables, TV fibers and telecommunication fibers.
2. All techniques and equipment may not be separately developed and modified and remain the same as they are. Technique and equipment updates can be performed without any “delivery pains”. All equipment, techniques as well as their developments synchronize with the world, realize general purposes and converge with the world. It is easy and feasible to realize this technique economically and reliably with low threshold.
3. It can bring maximal benefit to consumers, which is the largest weight for marketing competition as well as the source impetus to develop our information industry.
4. It has broad bandwidth. The speed with the lowest scheme is higher than that of ADSL by 100 times and has extensible space for bandwidth. It can build up a feasible and ideal physical network platform for the broadband “Stream Media” technique to be implemented.
5. The number of its users is huge. Our country already has one billion electricity users, who can be administrated within an electric power system as a whole and comprehensively at the same time. We can combine it with the electric power and network infrastructure modification project that has been launched throughout cities and countries of the country to drive the modernization of electric power industry with information industry.
6. The network topology of broadband transmission can be well matched with that of electric power transmission.
7. Optical transmission and electric power transmission have no interference with each other. Two transmission media can go on the same way completely.
8. During network wiring, electricity (electric power) connection won't affect the transmission and connection of broadband signal completely, and broadband signal connection can guarantee normal connection of electricity (electric power).

### BRIEF DESCRIPTION OF THE DRAWINGS

Hereafter it will give out a further description about this invention in combination with the attached drawing and its implementation mode:

FIG. 1 is the illustration for the structures of a broadband transmission network of 10 KV power distribution network and a broadband access transmission network of low-voltage power distribution network (HFC);

FIG. 2 is the illustration for the structures of a broadband transmission network of 10 KV power distribution network and an all-optical broadband access transmission network of low-voltage power distribution network;

FIG. 3 is the illustration for the structures of a broadband transmission network of 10 KV power distribution network and a wireless broadband access transmission network of low-voltage power distribution network;

FIG. 4 is the illustration for the structure of an insulating waterproof outer jacket 6;

FIG. 5 is the illustration for the structure of a tap 5;

FIG. 6 is the sectional view of a tap 5;

FIG. 7 is the illustration for the assembly of a wire pole 14;

FIG. 8 is the zoom-in illustration of supporting insulator of overhead power line or broadband compound power line.

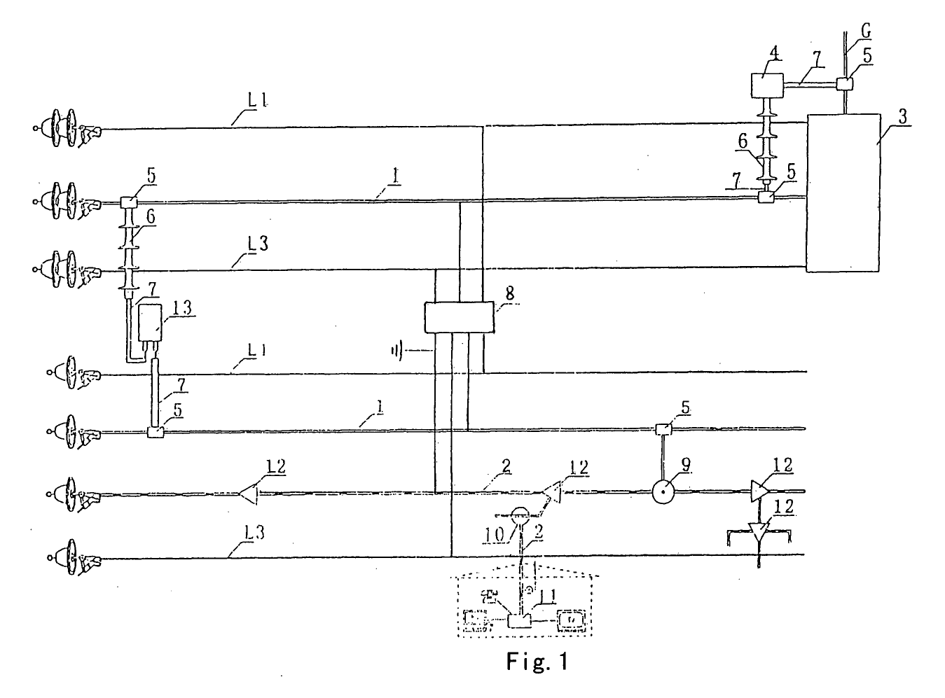

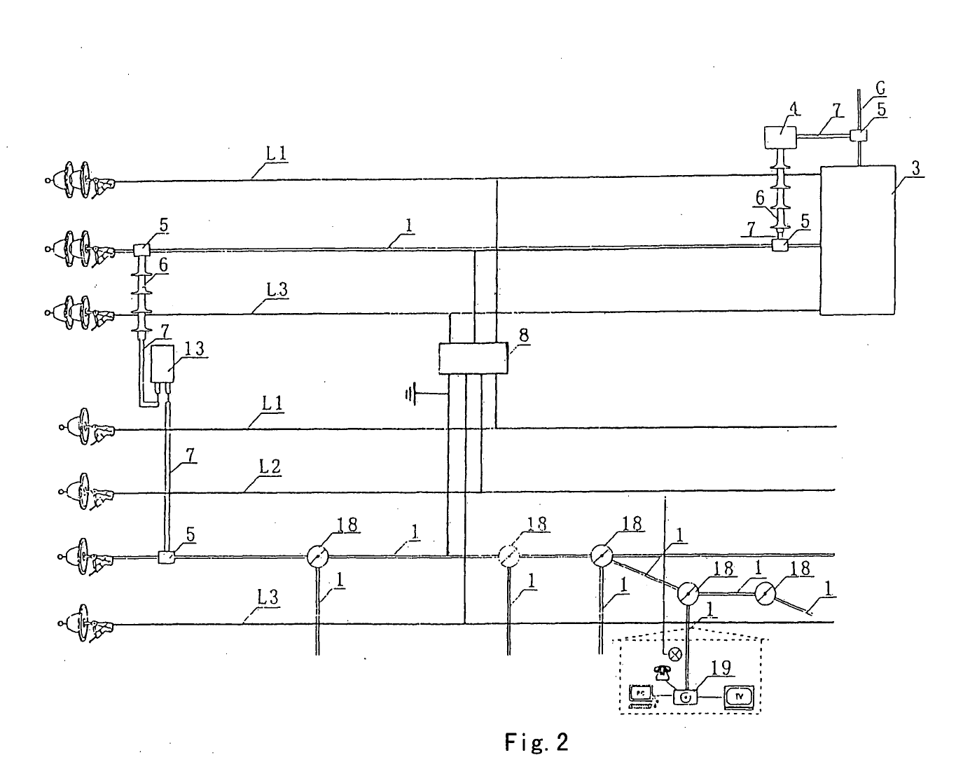

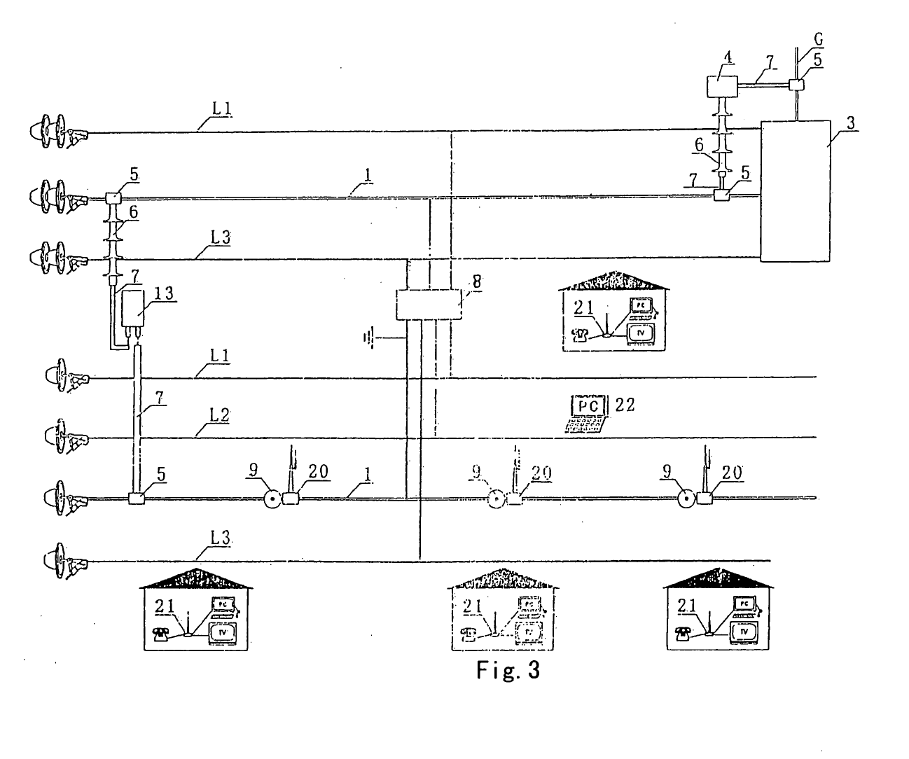

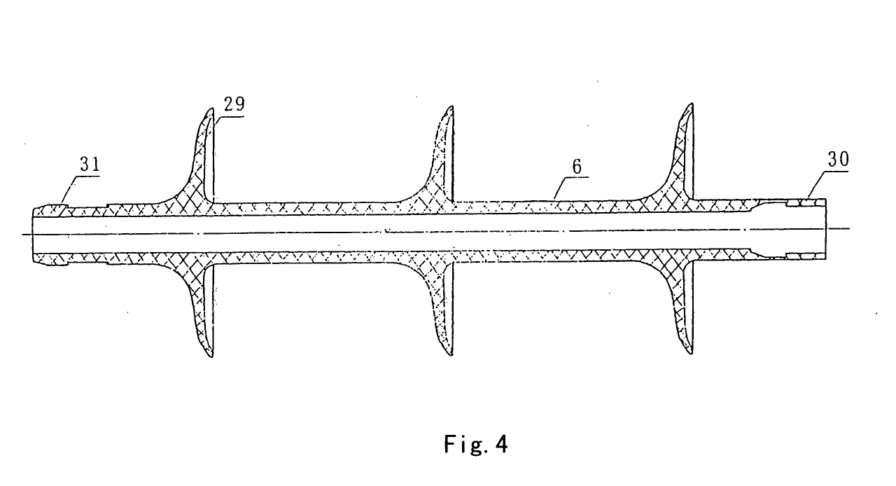

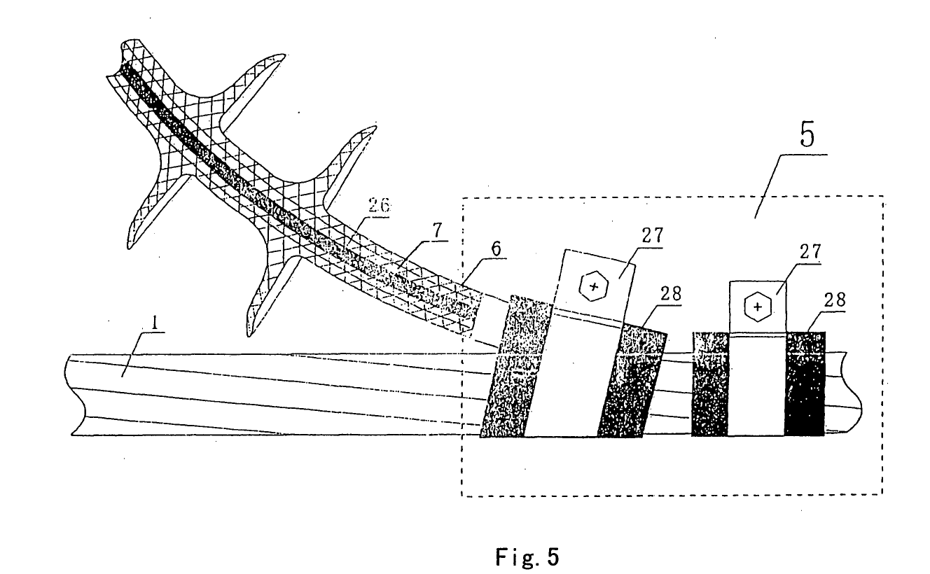

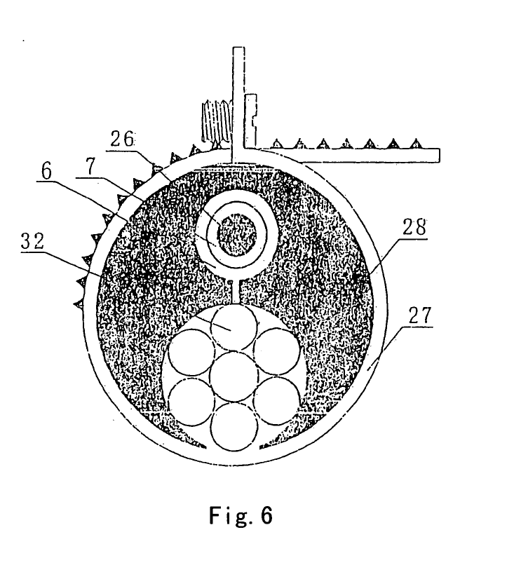

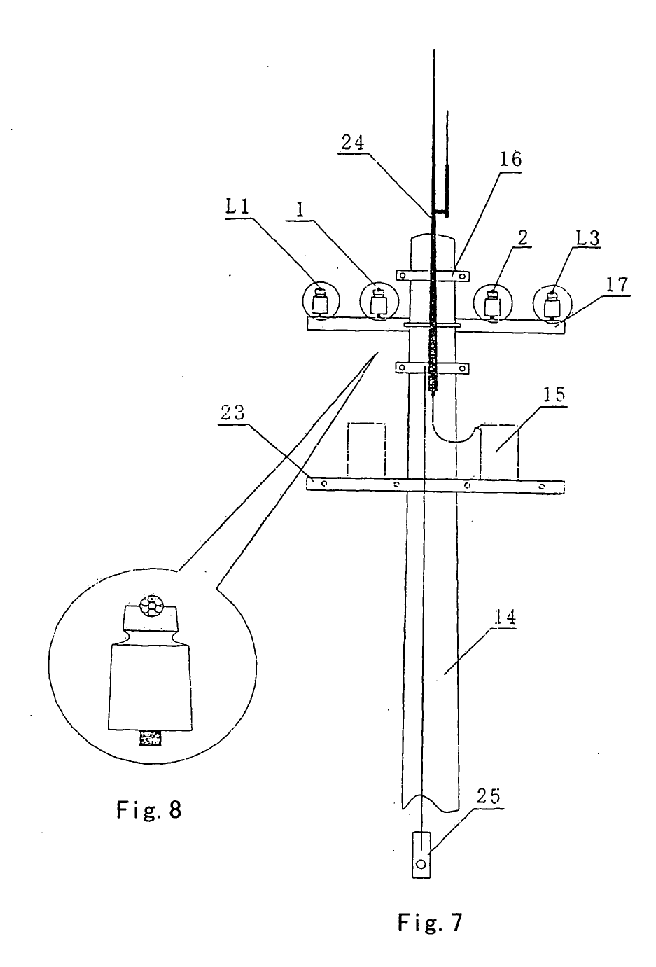

### DETAILED DESCRIPTION OF THE EMBODIMENTS

This network project is mainly to realize a broadband access network by integrating the power distribution networks of 10 KV voltage and low-voltage (three-phase four-wire system of 200/380V) with broadband access transmission network to form the physical foundation for broadband transmission network of “four-network convergence”. Following is the detailed description of three kinds of wiring implementation schemes for broadband access transmission network.

(1) Broadband Access Transmission Network of Low-Voltage Power Distribution Network (HFC)
a. Network wiring: the phase B necessary for routing 10 KV power distribution line provided by transformer substation for customers (or other phases) is used as optical compound electric power line 1. And then the phase B necessary for routing in low-voltage power distribution line within the service area of 10 KV line (also can be other phases) is used as optical compound electric line 1. At the same time, set all necessary neutral wires that TN-C connects in protection zero mode as coaxial cable compound line 2. The neutral wire has its peculiar electric feature. One is prohibiting from loading fuse for ON-OFF on the neutral wire. That is, this wire must connect each customer directly with his electric appliance from the beginning to the end, i.e. every family must have the wire entered their houses. The other is that the neutral wire must be connected with the ground uniformly and repeatedly. If it is permitted, it is better to put every service line and lead-in wire to earth. Theoretically, the neutral wire is uncharged, which is exactly meet with each feature requirement of coaxial cable compound wire 2 for concurrent transmission of electric power and broadband signal. Thus the broadband wiring project and the electric power wire extending project can be easily and conveniently finished once-and-for-all. Networking with this wiring method is exact the network theory for current hottest Hybrid Fiber Coaxial (HFC) broadband network, which has no modification for existing (HFC) technology and equipment. Its technical standards and development keep pace with current technology. It only makes use of the line resources of electric power network and doesn't need to add any other equipment, keeping consistent with the two-way modification technology of the broadcast and TV network. The optical node 9 and optical fiber connector 13 in the wiring are fixed on the proper wire pole 14 selected. The optical node 9 and the optical connector 13 are mounted in the protection installation box 15. The protection installation box 15 is fixed on wire pole 14 reliably by holder 23. The optical node 9 and the optical fiber connector 13 are mounted in the protection installation box 15. The protection installation box 15 is fixed on wire pole 14 reliably by holder 23. The optical node 9 can be provided with electric power from the electric power line of the wire pole 14 after metering if necessary. Reference numeral “17” indicates the load-carrying cross arm for electric power line and compound electric power line.
b. Network and information splicing: the optical signal sent through optical compound line G from region or county (city) Metropolitan Area Network is branched by taps 5 and sent to machine room 4 before entering transformer substation 3. The machine room 4 can be cancelled if necessary to perform direct connection. Or the machine room 4 can be built together with the transformer substation 3 or in other proper places; or it can be put in a box and be fixed on proper wire pole 14 or in other places. And then after a serial of processing over the broadband signal, the broadband signal is connected with the optical fiber in optical compound electric power line 1 of 10 KV line that provides power for customers in transformer substation 3 via taps 5 respectively. The lead-in optical fiber before shunting must be jacketed with insulating waterproof outer jacket 6 and insulating jacket 7. The whole lead-in optical fiber is not permitted to connect with metal to guarantee high-voltage insulating and security as well as waterproof. Then the optical signal is transferred via optical fiber compound electric power line 1 to the scope of low-voltage power supply line of each transformer 8. The optical fiber via taps 5 is separated at proper point of low-voltage line within this scope, and then after passing through optical fiber connector 13, is connected with the fiber in optical fiber compound electric power line 1 of the low-voltage three-phase four-line electric network via tap 5. At this time, the optical signal has entered the low-voltage power distribution network. The optical node 9 is mounted at proper point of the low-voltage power distribution network. The broadband signal outputted from the optical node 9 connects with the coaxial cable compound line 2 in low-voltage power distribution network. The broadband electric signal is connected to each customer via coaxial cable compound line 2 through several splitters 10. Each optical node 9 ordinarily covers from 300 to 500 customers; or it can cover less customers according to specific situation of development, which makes each customer share broader bandwidth. Customer makes Cable Modem (CM) to connect his terminal with the network, which forms (HFC) networking scheme. To guarantee the quality of signal level, the whole line is equipped with two-way line amplifiers 12.

(2) All-Optical Broadband Access Transmission Network of Low-Voltage Power Distribution Network
a. Network wiring: the phase B necessary for routing 10 KV power distribution line provided by transformer substation 3 for customers (or other phases) is used as optical compound electric power line 1. And then the neutral wire (also can be other phrases) in low-voltage power distribution line within the service area of 10 KV line is used as optical compound electric line 1. And then each customer terminal 19 is connected via optical compound electric power line 1 after passing through several splitters 10. This access network is all wired with optical fiber. The optical splitter 18 in the wiring is fixed on proper wire pole 14 selected or other places.
b. Network and information splicing: the optical signal sent through optical compound line G from region or county (city) Metropolitan Area Network is branched by taps 5 and sent to machine room 4 before entering transformer substation 3. The machine room can be cancelled if necessary to perform direct connection. Or the machine room 4 can be built together with the transformer substation 3 or in other proper places; or it can be put in a box and be fixed on proper wire pole 14 or in other places. And then after a serial of processing over the broadband signal, the broadband signal is connected with the optical fiber in optical compound electric power line 1 of 10 KV line that provides power for customers in transformer substation 3 via taps 5 respectively. The lead-in optical before shunting must be jacketed with insulating jacket 7 and insulating waterproof outer jacket 6. The whole lead-in optical fiber is not permitted to connect with metal to guarantee high-voltage insulating and security as well as waterproof. Then the optical signal is transferred via optical fiber compound electric power line 1 to the scope of low-voltage power supply line of each transformer 8. The optical fiber is separated via taps 5 at proper point of low-voltage line within this scope, and then after passing through optical fiber connector 13, is connected with the fiber in optical fiber compound electric power line 1 of the low-voltage three-phase four-line electric network via tap 5. At this time, the optical signal has entered the low-voltage power distribution network. The optical signal in the optical fiber compound power distribution line 1 of low-voltage electric network is sent to each customer terminal 19 after passing through several optical splitters 13 to realize fiber to the house (FTTH), (FTTB), or (FTTD).

(3) Wireless Broadband Access Transmission Network of Low-Voltage Power Distribution Network
a. Network wiring: the phase B necessary for routing 10 KV power distribution line provided by transformer substation 3 for customers (or other phases) is used as optical compound electric power line 1. And then the neutral wire (also can be other phrases) in low-voltage power distribution line within the service area of 10 KV line is used as optical compound electric line 1. Then, after thorough and repeated argumentation and planning for the whole network of low-voltage power supply through combining with the environment such as geographic condition and customer distribution, an on-site investment is performed to select proper site, and the optical node 9 and radio transceiver 20 are mounted on proper wire pole 14 selected. Radio transceiver 20 realizes wireless connection with the fixed terminal 21 and the mobile terminal 22 of customer's via electromagnetic signal or optical signal. The optical node 9 and radio transceiver 20 in the wiring are mounted in the protection installation box 15. The protection installation box 15 is mounted on the fixed holder 23 and is fixed on the wire pole 14 with cross-core screw bar. Reference numeral 24 indicates the radio system, which is fixed on the wire pole 14 with anchor ear 16 and connects with the radio transceiver 20 in the protection installation box 15 via high-frequency signal feeder. If the radio transceiver 20 connects with fixed terminal 21 and mobile terminal 22 in optical signal or other signals, the equipment on the both sides are different. The secure grounding polar 25 must be put to earth to guarantee security. If devices such as optical node 9 and radio transceiver 20 that are fixed on wire pole 14 need power supply, they can be provided with power from the low-voltage electric power line on the wire pole 14 after metering. The feature of this network structure is: the transceiver 20 can be low power, densely distributed, small investment and be convenient for networking and installation.
b. Network and information splicing: the optical signal sent through optical compound line G from aerial or county (city) Metropolitan Area Network is branched by taps 5 and sent to machine room 4 before entering transformer substation 3. The machine room can be cancelled if necessary to perform direct connection. Or the machine room 4 can be built together with the transformer substation; or it can be put in a box as a module and be fixed on proper wire pole 14 or in other places. And then after a serial of processing over the broadband signal, the broadband signal is connected with the optical fiber in optical compound electric power line 1 of 10 KV line that provides power for customers in transformer substation 3 via taps 5 respectively. The lead-in optical before shunting must be jacketed with insulating jacket 7 and insulating waterproof outer jacket 6. The whole lead-in optical fiber is not permitted to connect with metal to guarantee high-voltage insulating and security as well as waterproof. Then the optical signal is transferred via optical fiber compound electric power line 1 to the scope of low-voltage power supply line of each transformer 3. The optical fiber is separated via taps 5 at proper point of low-voltage line within this scope, and then after passing through optical fiber connector 13, is connected with the fiber in optical fiber compound electric power line 1 of the low-voltage three-phase four-line electric network via tap 5. At this time, the optical signal has entered the optical fiber compound electric power line 1 of neutral wire part in the low-voltage power distribution network. And then the optical node 9 and radio transceiver 20 are mounted on proper wire pole 14 selected. Radio transceiver 20 connects with the fixed terminal 21 and mobile terminal 22 of customer over the air to realize broadband wireless connection.

1. A broadband access transmission network integrating the functions of electric power network, telecommunication network, TV network and Internet comprises a broadband transmission network of 10 KV power distribution network and a broadband access transmission network of low-voltage power distribution network, these two transmission networks are connected via distribution transformer (8) and optical fiber connector (13); the broadband transmission network of 10 KV power distribution network comprises optical compound power lines (1), power wires (L1, L3), transformer substation (3), machine room (4), taps (5), insulating waterproofing outer jacket (6), insulating jacket (7), and optical fiber connector (13); the broadband access transmission network of low-voltage power distribution network comprises the optical compound power lines (1), coaxial cable compound power lines (2), power wires (L1, L3), taps (5), insulting jacket (7), optical node (9), distributor (10), modems (11) and two-way amplifiers (12), it is characterized in that:
the optical compound power lines (1) and power wires (L1, L3) of the broadband transmission network of 10 KV power distribution network connect with the transformer substation (3); one end of the fiber compound power line (1) is connected with machine room (4) via taps (5), insulating waterproofing outer jacket (6) and insulating jacket (7); machine room (4) is connected with the fiber compound lines of backbone network (G) via taps (5); the other end of the fiber compound power line (1) is connected with fiber connector 13 via taps (5), insulating waterproof outer jacket (6) and insulating jacket (7); one end of the fiber compound power line (1) of broadband access transmission network of low-voltage power distribution network is connected with fiber connector (13) via taps (5) and insulating jackets (7), and the other end is connected with coaxial cable compound lines (2) via taps (5) and fiber node (9); coaxial cable compound line (2) is equipped with two-way amplifier (12), which is connected with client modem (11) via coaxial cable compound lines (2) and distributor (10).

2. The broadband transmission network integrating the functions of electric power network, telecommunication network, TV network and Internet according to claim 1, wherein the fiber compound power lines (1) of all optical broadband access transmission network of low-voltage power distribution network is connected with client terminal (19) via optical splitter (18).

3. The broadband transmission network integrating the functions of electric power network, telecommunication network, TV network and Internet according to claim 1, wherein the fiber compound power lines (1) of wireless broadband access transmission network of low-voltage power distribution network is equipped with a radio transceiver (20) that matches with the fixed terminal (21) and mobile terminal (22) of customer.

4. The broadband transmission network integrating the functions of electric power network, telecommunication network, TV network and Internet according to claim 1, wherein fastening element (27) of taps (5) is equipped with compound insulting soft-ring (28) as well as standby stuffing conductor band (32).

5. The broadband transmission network integrating the functions of electric power network, telecommunication network, TV network and Internet according to claim 1, wherein the surface of insulating waterproof outer jacket (6) is equipped with waterproof apron (29) and both ends are equipped with female buckle (30) and male buckle (31).

6. The broadband transmission network integrating the functions of electric power network, telecommunication network, TV network and Internet according to claim 1, wherein the optical compound power line (1) is a compound power line composed by fiber, insulating socket and power transmission conductor; the coaxial compound line (2) is a compound power line composed by inner conductor, insulation protection layer, load-carrying layer and electric power transmission layer.
